(19) United States
(12) Patent Application Publication
(10) Pub. No.: US 2026/0020468 A1
(43) Pub. Date: Jan. 15, 2026

(54) DISPLAY DEVICE, VEHICLE INCLUDING THE SAME, AND ELECTRONIC DEVICE INCLUDING THE SAME

(71) Applicant: Samsung Display Co., Ltd., Yongin-Si (KR)

(72) Inventor: DALE YIM, Yongin-si (KR)

(21) Appl. No.: 19/035,888

(22) Filed: Jan. 24, 2025

(30) Foreign Application Priority Data
Jul. 15, 2024 (KR) 10-2024-0093134

(51) Int. Cl. H10K 59/50; H10K 59/35

(52) U.S. Cl. CPC H10K 59/50; H10K 59/35

(57) ABSTRACT

A display device includes a substrate, a pixel electrode disposed in a first light emitting area, a second light emitting area, and a transmissive area, a first intermediate layer disposed in the first light emitting area and including a first light emitting layer that emits a first light, a second intermediate layer disposed in the second light emitting area and including a second light emitting layer that emits a second light and a third light emitting layer that emits a third light, a third intermediate layer disposed in the transmissive area and including an organic layer including an electrochromic material, and a common electrode.

### CROSS-REFERENCE TO RELATED APPLICATION(S)

This application claims priority under 35 USC § 119 to Korean Patent Application No. 10-2024-0093134 filed on Jul. 15, 2024, in the Korean Intellectual Property Office (KIPO), the entire disclosure of which is incorporated by reference herein.

### BACKGROUND

### 1. Field

Embodiments relate to a display device. More specifically, embodiments relate to a transparent display device, a vehicle including the display device, and an electronic device including the display device.

### 2. Description of the Related Art

A display device is a device that displays an image that provides visual information to a user, and may include a transparent display device that enables a user to see another side (e.g., a rear side) through one side (e.g., a front side).

The transparent display device may include a plurality of light emitting areas and a plurality of transmissive areas. The light emitting areas may emit light, and the transmissive areas may transmit light. A light transmittance of the transmissive areas may be higher than a light transmittance of the light emitting areas. Accordingly, the user may not only visually recognize an image displayed through the light emitting areas, and also visually recognize an object or image located behind the display device by light transmitted through the transmissive areas.

### SUMMARY

Embodiments provide a display device that adjusts transparency.

Embodiments provide a vehicle including the display device.

Embodiments provide an electronic device including the display device.

A display device according to an embodiment of the present disclosure includes a substrate defining a first light emitting area, a second light emitting area, and a transmissive area, a pixel electrode disposed in the first light emitting area, the second light emitting area, and the transmissive area on the substrate, a first intermediate layer disposed in the first light emitting area on the pixel electrode and including a first light emitting layer that emits a first light, a second intermediate layer disposed in the second light emitting area on the pixel electrode and including a second light emitting layer that emits a second light and a third light emitting layer that emits a third light, a third intermediate layer disposed in the transmissive area on the pixel electrode and including an organic layer including an electrochromic material, and a common electrode disposed on the first intermediate layer, the second intermediate layer, and the third intermediate layer.

In an embodiment, the second light emitting area may include a first sub-area and a second sub-area spaced apart from the first sub-area, the first sub-area and the second sub-area may be adjacent to each other, and the transmissive area may be disposed between the first sub-area and the second sub-area.

In an embodiment, the second intermediate layer may include a first sub-layer disposed in the first sub-area on the pixel electrode, in which the second light emitting layer is disposed between the substrate and the third light emitting layer, and a second sub-layer disposed in the second sub-area on the pixel electrode, in which the third light emitting layer is disposed between the substrate and the second light emitting layer.

In an embodiment, the first light emitting area, the first sub-area, and the transmissive area may define a first sub-pixel, the first light emitting area, the second sub-area, and the transmissive area may define a second sub-pixel, and the first sub-pixel and the second sub-pixel may be alternately arranged along a first direction and a second direction intersecting the first direction.

In an embodiment, in the first sub-pixel, the first sub-area may be spaced apart from the first light emitting area in the first direction, and the transmissive area may be spaced apart from the first sub-area in the first direction.

In an embodiment, in the second sub-pixel, the first light emitting area may be spaced apart from the second sub-area in the first direction, and the transmissive area may be spaced apart from the first light emitting area in the first direction.

In an embodiment, the organic layer may include viologen.

In an embodiment, the first light emitting layer may include a first sub-light emitting layer that emits the first light, and a second sub-light emitting layer that is disposed on the first sub-light emitting layer and emits the first light.

In an embodiment, the first intermediate layer may further include a charge generation layer disposed between the first sub-light emitting layer and the second sub-light emitting layer, and the second intermediate layer may further include a sub-common electrode and a sub-pixel electrode disposed between the second light emitting layer and the third light emitting layer.

In an embodiment, the first light may be light of a blue wavelength band, the second light may be light of a red wavelength band, and the third light may be light of a green wavelength band.

A vehicle according to an embodiment of the present disclosure includes a vehicle body defining an interior space, and a display device disposed on the vehicle body. The display device includes a substrate defining a first light emitting area, a second light emitting area, and a transmissive area, a pixel electrode disposed in the first light emitting area, the second light emitting area, and the transmissive area on the substrate, a first intermediate layer disposed in the first light emitting area on the pixel electrode and including a first light emitting layer that emits a first light, a second intermediate layer disposed in the second light emitting area on the pixel electrode and including a second light emitting layer that emits a second light and a third light emitting layer that emits a third light, a third intermediate layer disposed in the transmissive area on the pixel electrode and including an organic layer including an electrochromic material, and a common electrode disposed on the first intermediate layer, the second intermediate layer, and the third intermediate layer.

In an embodiment, the second light emitting area may include a first sub-area and a second sub-area spaced apart from the first sub-area, the first sub-area and the second sub-area may be adjacent to each other, and the transmissive area may be disposed between the first sub-area and the second sub-area.

In an embodiment, the second intermediate layer may include a first sub-layer disposed in the first sub-area on the pixel electrode, in which the second light emitting layer is disposed between the substrate and the third light emitting layer, and a second sub-layer disposed in the second sub-area on the pixel electrode, in which the third light emitting layer is disposed between the substrate and the second light emitting layer.

In an embodiment, the first light emitting area, the first sub-area, and the transmissive area may define a first sub-pixel, the first light emitting area, the second sub-area, and the transmissive area may define a second sub-pixel, and the first sub-pixel and the second sub-pixel may be alternately arranged along a first direction and a second direction intersecting the first direction.

In an embodiment, in the first sub-pixel, the first sub-area may be spaced apart from the first light emitting area in the first direction, and the transmissive area may be spaced apart from the first sub-area in the first direction, and in the second sub-pixel, the first light emitting area may be spaced apart from the second sub-area in the first direction, and the transmissive area may be spaced apart from the first light emitting area in the first direction.

In an embodiment, the organic layer may include viologen.

In an embodiment, the first light emitting layer may include a first sub-light emitting layer that emits the first light, and a second sub-light emitting layer that is disposed on the first sub-light emitting layer and emits the first light.

In an embodiment, the first intermediate layer may further include a charge generation layer disposed between the first sub-light emitting layer and the second sub-light emitting layer, and the second intermediate layer may further include a sub-common electrode and a sub-pixel electrode disposed between the second light emitting layer and the third light emitting layer.

In an embodiment, the first light may be light of a blue wavelength band, the second light may be light of a red wavelength band, and the third light may be light of a green wavelength band.

In an embodiment, the vehicle body may include a front window glass, and the display device may be disposed on the front window glass.

An electronic device according to an embodiment of the present disclosure includes a display device, and a power module that supplies power to the display device. The display device includes a substrate defining a first light emitting area, a second light emitting area, and a transmissive area, a pixel electrode disposed in the first light emitting area, the second light emitting area, and the transmissive area on the substrate, a first intermediate layer disposed in the first light emitting area on the pixel electrode and including a first light emitting layer that emits a first light, a second intermediate layer disposed in the second light emitting area on the pixel electrode and including a second light emitting layer that emits a second light and a third light emitting layer that emits a third light, a third intermediate layer disposed in the transmissive area on the pixel electrode and including an organic layer including an electrochromic material, and a common electrode disposed on the first intermediate layer, the second intermediate layer, and the third intermediate layer.

In a display device according to embodiments of the present disclosure, the display device may include an organic layer disposed in a transmissive area and including an electrochromic material. The transmissive area may transmit incident light or emit light of a specific wavelength band, and thus transparency of the display device may be adjusted.

### BRIEF DESCRIPTION OF THE DRAWINGS

FIG. 1 is a plan view illustrating a display device according to an embodiment of the present disclosure.

FIG. 2 is an enlarged plan view of a portion of a display area of the display device of FIG. 1.

FIG. 3 is a cross-sectional view taken along line I-I′ of FIG. 2.

FIG. 4 is a cross-sectional view taken along line II-II′ of FIG. 2.

FIGS. 5 and 6 are cross-sectional views illustrating an intermediate layer included in the display device of FIG. 1.

FIG. 7 is a plan view illustrating a display device according to an embodiment of the present disclosure.

FIG. 8 is a cross-sectional view taken along line III-III′ of FIG. 7.

FIG. 9 is a cross-sectional view taken along line IV-IV′ of FIG. 7.

FIGS. 10 and 11 are cross-sectional views illustrating an intermediate layer included in the display device of FIG. 7.

FIG. 12 is a view schematically illustrating a vehicle according to an embodiment of the present disclosure.

FIG. 13 is a view schematically illustrating a portion of an interior of the vehicle of FIG. 12.

FIG. 14 is a block diagram illustrating an electronic device according to an embodiment of the present disclosure.

FIG. 15 is a schematic view illustrating electronic devices according to embodiments of the present disclosure.

### DETAILED DESCRIPTION OF THE EMBODIMENTS

Hereinafter, embodiments of the present disclosure will be described in more detail with reference to the accompanying drawings. The same reference numerals are used for the same components in the drawings, and redundant descriptions of the same components will be omitted.

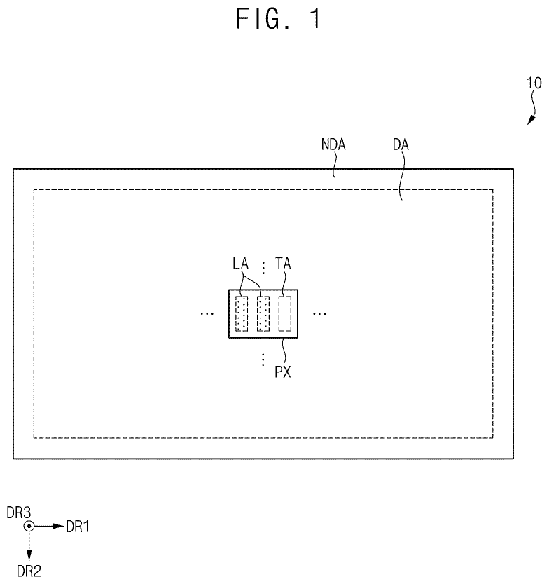

FIG. 1 is a plan view illustrating a display device 10 according to an embodiment of the present disclosure.

Referring to FIG. 1, the display device 10 may include a display area DA and a non-display area NDA. The display area DA may be an area that generates light to display an image. The non-display area NDA may be an area that does not display an image. The non-display area NDA may be located around the display area DA. For example, the non-display area NDA may surround the display area DA in a plan view.

A plurality of pixels PX may be disposed in the display area DA. The pixels PX may be arranged in a matrix form along a first direction DR1 and a second direction DR2 intersecting the first direction DR1. Each of the pixels PX may emit light.

In an embodiment, each of the pixels PX may include a light emitting area LA that emits light and a transmissive area TA that transmits external light. For example, the light emitting area LA may be an opaque area in which external light is blocked, and the transmissive area TA may be a transparent area through which external light is transmitted to observe an object located on an opposite side. The transmissive area TA may be an area in which transparency may be adjusted. For example, the light emitting area LA may be an area in which a light emitting element is disposed, and the transmissive area TA may be an area in which an electrochromic element is disposed.

As light is emitted from the light emitting area LA of each of the pixels PX, the display area DA may display an image (e.g., in a third direction DR3 intersecting each of the first direction DR1 and the second direction DR2), and a user may visually recognize the image displayed by the display device 10. In addition, as light incident on the transmissive area TA of each of the pixels PX is transmitted, the user may visually recognize an object, an image, or the like located behind the display device 10. A detailed description of this will be described later.

Lines connected to the pixels PX may be further disposed in the display area DA. For example, the lines may include a data voltage line, a gate signal line, a power line, or the like.

Drivers for driving the pixels PX may be disposed in the non-display area NDA. For example, the drivers may include a data driver, a gate driver, a power voltage generator, a timing controller, or the like. The pixels PX may emit light based on signals received from the drivers.

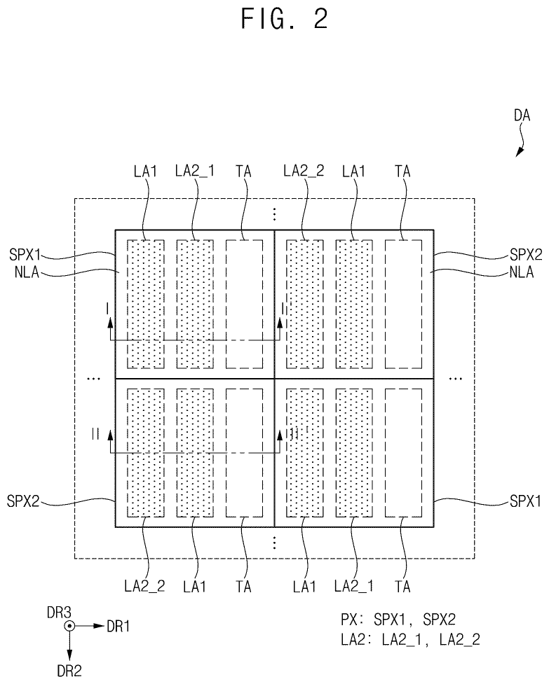

FIG. 2 is an enlarged plan view of a portion of the display area DA of the display device 10 of FIG. 1.

Referring to FIG. 2, the pixels PX disposed in the display area DA may include a first light emitting area LA1, a second light emitting area LA2, a transmissive area TA, and a non-light emitting area NLA. The first and second light emitting areas LA1 and LA2 may correspond to the light emitting area LA of FIG. 1.

Each of the first light emitting area LA1 and the second light emitting area LA2 may be an area that emits light. The first light emitting area LA1 and the second light emitting area LA2 may emit light of different wavelength bands.

The transmissive area TA may be an area that transmits incident light. In addition, the transmissive area TA may be an area that emits light. The transmissive area TA may emit light of a different wavelength band from the first light emitting area LA1 and the second light emitting area LA2, or may emit light of a same wavelength band as at least one of the first light emitting area LA1 and the second light emitting area LA2. In an embodiment, the transmissive area TA may be an area in which transmittance of light is adjusted. Since the display device 10 includes the transmissive area TA, transparency of the display device 10 may be adjusted (or controlled).

The non-light emitting area NLA may be an area that does not emit light. The non-light emitting area NLA may define the first light emitting area LA1, the second light emitting area LA2, and the transmissive area TA. The non-light emitting area NLA may surround the first light emitting area LA1, the second light emitting area LA2, and the transmissive area TA in a plan view.

In an embodiment, the second light emitting area LA2 may include a first sub-area LA2_1 and a second sub-area LA2_2 spaced apart from the first sub-area. The first and second sub-areas LA2_1 and LA2_2 may be adjacent to each other, and the transmissive area TA may be disposed between the first and second sub-areas LA2_1 and LA2_2. For example, the first and second sub-areas LA2_1 and LA2_2 may emit light of different brightness. The first and second sub-areas LA2_1 and LA2_2 may emit light of substantially the same or similar wavelength band, but brightness of light emitted from the first and second sub-areas LA2_1 and LA2_2 may be different from each other.

The pixels PX disposed in the display area DA may include a first sub-pixel SPX1 and a second sub-pixel SPX2. The first sub-pixel SPX1 and the second sub-pixel SPX2 may be alternately arranged along the first direction DR1 and the second direction DR2.

The first light emitting area LA1, the first sub-area LA2_1 of the second light emitting area LA2, and the transmissive area TA may define the first sub-pixel SPX1, and the first light emitting area LA1, the second sub-area LA2_2 of the second light emitting area LA2, and the transmissive area TA may define the second sub-pixel SPX2.

The first sub-pixel SPX1 may include the first light emitting area LA1, the first sub-area LA2_1 of the second light emitting area LA2, and the transmissive area TA, and the second sub-pixel SPX2 may include the first light emitting area LA1, the second sub-area LA2_2 of the second light emitting area LA2, and the transmissive area TA.

In an embodiment, in the first sub-pixel SPX1, the first sub-area LA2_1 may be spaced apart from the first light emitting area LA1 in the first direction DR1, and the transmissive area TA may be spaced apart from the first sub-area LA2_1 in the first direction DR1. In the second sub-pixel SPX2, the first light emitting area LA1 may be spaced apart from the second sub-area LA2_2 in the first direction DR1, and the transmissive area TA may be spaced apart from the first light emitting area LA1 in the first direction DR1. That is, in the first and second sub-pixels SPX1 and SPX2, the arrangement of the transmissive area TA may be same, but the arrangement of the first and second light emitting areas LA1 and LA2 may be different from each other.

Accordingly, the first light emitting area LA1 and the second light emitting area LA2 may be alternately arranged along the second direction DR2. Specifically, the first light emitting area LA1 and the second sub-area LA2_2 may be alternately arranged along the second direction DR2, and the first light emitting area LA1 and the first sub-area LA2_1 may be alternately arranged along the second direction DR2. However, the present disclosure is not limited thereto, and the arrangement of the first and second light emitting areas LA1 and LA2 and the transmissive area TA in the first and second sub-pixels SPX1 and SPX2 (or, in the pixels PX) may be variously changed.

Although FIGS. 1 and 2 illustrate that each of the pixel PX (i.e., the first and second sub-pixels SPX1 and SPX2), the first light emitting area LA1, the second light emitting area LA2 (i.e., the first and second sub-areas LA2_1 and LA2_2), and the transmissive area TA have a rectangular planar shape, the present disclosure is not limited thereto, and shapes of the pixel PX (i.e., the first and second sub-pixels SPX1 and SPX2), the first light emitting area LA1, the second light emitting area LA2 (i.e., the first and second sub-areas LA2_1 and LA2_2), and the transmissive area TA may be variously changed.

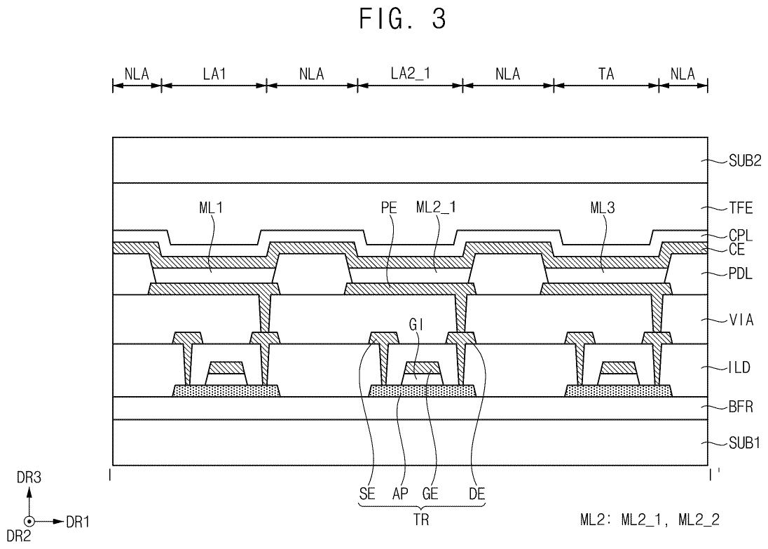

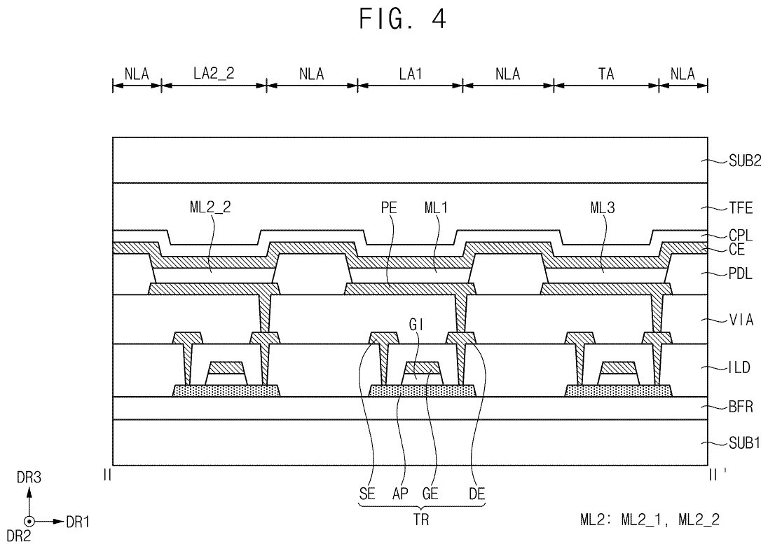

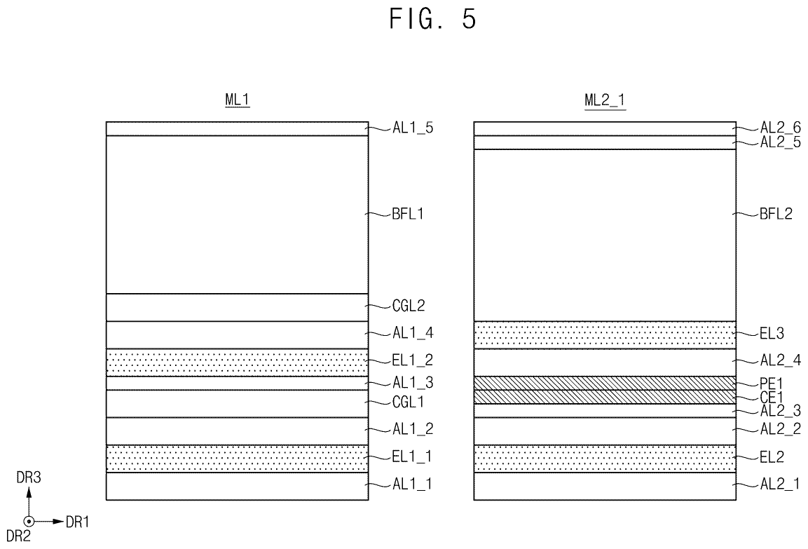

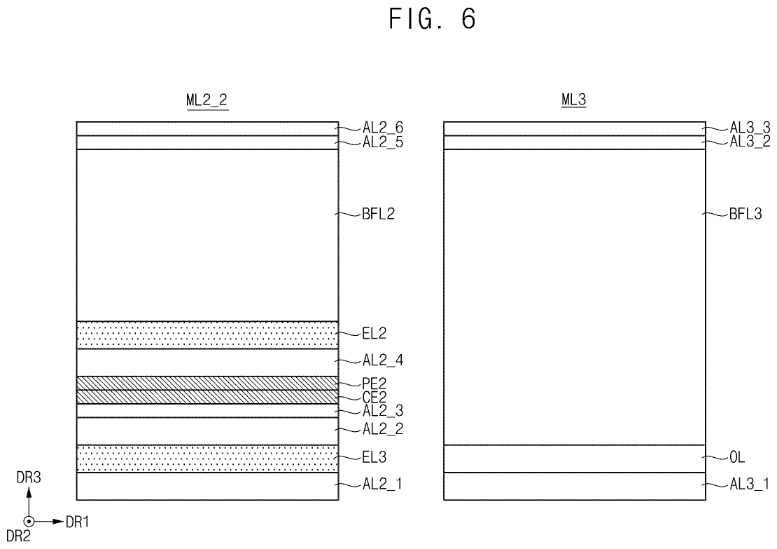

FIG. 3 is a cross-sectional view taken along line I-I′ of FIG. 2. FIG. 4 is a cross-sectional view taken along line II-II′ of FIG. 2. FIGS. 5 and 6 are cross-sectional views illustrating an intermediate layer included in the display device of FIG. 1.

For example, FIG. 3 may be a cross-sectional view illustrating the first sub-pixel SPX1. FIG. 4 may be a cross-sectional view illustrating the second sub-pixel SPX2. FIG. 5 may be a cross-sectional view illustrating a first intermediate layer ML1 disposed in the first light emitting area LA1 and a first sub-layer ML2_1 of a second intermediate layer ML2 disposed in the first sub-area LA2_1 of the second light emitting area LA2. FIG. 6 may be a cross-sectional view illustrating a second sub-layer ML2_2 of the second intermediate layer ML2 disposed in the second sub-area LA2_2 of the second light emitting area LA2 and a third intermediate layer ML3 disposed in the transmissive area TA.

Referring to FIGS. 2, 3, 4, 5, and 6, the display device 10 may include a first substrate SUB1, a buffer layer BFR, a transistor TR, a gate insulating layer GI, an interlayer insulating layer ILD, a via insulating layer VIA, a pixel electrode PE, a pixel defining layer PDL, the first intermediate layer ML1, the second intermediate layer ML2, the third intermediate layer ML3, a common electrode CE, a capping layer CPL, an encapsulation layer TFE, and a second substrate SUB2.

The transistor TR may include an active pattern AP, a gate electrode GE, a source electrode SE, and a drain electrode DE, and the second intermediate layer ML2 may include the first sub-layer ML2_1 and the second sub-layer ML2_2.

The first substrate SUB1 may define the first light emitting area LA1, the second light emitting area LA2 (i.e., the first and second sub-areas LA2_1 and LA2_2), the transmissive area TA, and the non-light emitting area NLA. The first substrate SUB1 may include a transparent material or an opaque material. For example, the first substrate SUB1 may include glass, plastic, flexible film, metal, or the like.

The buffer layer BFR may be disposed on the first substrate SUB1. The buffer layer BFR may prevent metal atoms, impurities, or the like from diffusing from the first substrate SUB1 to the transistor TR. In addition, when a surface of the first substrate SUB1 is not uniform, the buffer layer BFR may improve flatness of the surface of the first substrate SUB1. The buffer layer BFR may include an inorganic material such as silicon oxide (SiOₓ), silicon nitride (SiNₓ), silicon oxynitride (SiOₓN_{y}), or the like. These may be used alone or in combination with each other.

The active pattern AP may be disposed on the buffer layer BFR. The active pattern AP may include a source area, a drain area, and a channel area between the source area and the drain area. The active pattern AP may include a silicon semiconductor material or an oxide semiconductor material. In an embodiment, the active pattern AP may include an oxide semiconductor material. Examples of the oxide semiconductor material may include indium gallium zinc oxide (IGZO), indium tin zinc oxide (ITZO), or the like. These may be used alone or in combination with each other.

The gate insulating layer GI may be disposed on the active pattern AP, and may cover at least a portion of the active pattern AP. The gate insulating layer GI may overlap the channel area of the active pattern ACT in a plan view. The gate insulating layer GI may include an inorganic material such as silicon oxide, silicon nitride, silicon oxynitride, or the like. These may be used alone or in combination with each other.

The gate electrode GE may be disposed on the gate insulating layer GI. The gate electrode GE may overlap the channel area of the active pattern ACT and the gate insulating layer GI in a plan view. The gate electrode GE may include a metal, an alloy, a conductive metal oxide, a conductive metal nitride, a transparent conductive material, or the like.

The interlayer insulating layer ILD may be disposed on the gate electrode GE, and may cover the gate electrode GE. The interlayer insulating layer ILD may include an inorganic material such as silicon oxide, silicon nitride, silicon oxynitride, or the like. These may be used alone or in combination with each other.

The source electrode SE and the drain electrode DE may be disposed on the interlayer insulating layer ILD. The source electrode SE may be connected to the source area of the active pattern AP through a first contact hole penetrating the interlayer insulating layer ILD. In addition, the drain electrode DE may be connected to the drain area of the active pattern AP through a second contact hole penetrating the interlayer insulating layer ILD. For example, the source electrode SE and the drain electrode DE may include a metal, an alloy, a conductive metal oxide, a conductive metal nitride, a transparent conductive material, or the like. These may be used alone or in combination with each other.

Accordingly, the transistor TR including the active pattern AP, the gate electrode GE, the source electrode SE, and the drain electrode DE may be disposed on the first substrate SUB1.

The via insulating layer VIA may be disposed on the source electrode SE and the drain electrode DE, and may sufficiently cover the source electrode SE and the drain electrode DE. The via insulating layer VIA may include an organic material such as a phenol resin, an acrylic resin, a polyimide resin, a polyamide resin, a siloxane resin, an epoxy resin, or the like. These may be used alone or in combination with each other.

The pixel electrode PE may be disposed on the via insulating layer VIA. The pixel electrode PE may be disposed in the first light emitting area LA1, the first and second sub-areas LA2_1 and LA2_2 of the second light emitting area LA2, and the transmissive area TA, respectively. The pixel electrode PE may be electrically connected to the transistor TR. For example, the pixel electrode PE may be connected to the drain electrode DE (or the source electrode SE) of the transistor TR through a contact hole penetrating the via insulating layer VIA. The pixel electrode PE may include a metal, an alloy, a conductive metal oxide, a conductive metal nitride, a transparent conductive material, or the like. These may be used alone or in combination with each other.

The pixel defining layer PDL may be disposed in the non-light emitting area NLA on the via insulating layer VIA. The pixel defining layer PDL may cover at least a portion of the pixel electrode PE. The pixel defining layer PDL may define an opening extending to and exposing at least a portion of an upper surface of the pixel electrode PE. The pixel defining layer PDL may include an organic material such as an epoxy resin, a siloxane resin, or the like.

The first intermediate layer ML1, the second intermediate layer ML2, and the third intermediate layer ML3 may be disposed on the pixel electrode PE. The first intermediate layer ML1 may be disposed in the first light emitting area LA1, the first sub-layer ML2_1 of the second intermediate layer ML2 may be disposed in the first sub-area LA2_1 of the second intermediate layer ML2, the second sub-layer ML2_2 of the second intermediate layer ML2 may be disposed in the second sub-area LA2_2 of the second light emitting area LA2, and the third intermediate layer ML3 may be disposed in the transmissive area TA.

Each of the first, second, and third intermediate layers ML1, ML2, and ML3 may have a multi-layer structure. For example, the first, second, and third intermediate layers ML1, ML2, and ML3 may have different stacked structures.

In an embodiment, the first intermediate layer ML1 may have a structure in which a plurality of light emitting layers that emit light of a same wavelength band are stacked. For example, the first intermediate layer ML1 may have a structure in which a plurality of organic light emitting layers that emit light of a blue wavelength band are stacked, and may emit light of a blue wavelength band, but the present disclosure is not limited thereto.

The first intermediate layer ML1 may include a first auxiliary layer AL1_1, a first sub-light emitting layer EL1_1, a second auxiliary layer AL1_2, a first charge generation layer CGL1, a third auxiliary layer AL1_3, a second sub-light emitting layer EL1_2, a fourth auxiliary layer AL1_4, a second charge generation layer CGL2, a first buffer layer BFL1, and a fifth auxiliary layer AL1_5.

The first auxiliary layer AL1_1 may be disposed on the pixel electrode PE. The first auxiliary layer AL1_1 may have a single-layer structure or a multi-layer structure. For example, the first auxiliary layer AL1_1 may include a hole injection layer (HIL) and a hole transport layer (HTL).

The first sub-light emitting layer EL1_1 may be disposed on the first auxiliary layer AL1_1. The first sub-light emitting layer EL1_1 may emit light of a specific wavelength band, and may include a material that emits the light. For example, the first sub-light emitting layer EL1_1 may emit light of a blue wavelength band, but the present disclosure is not limited thereto.

The second auxiliary layer AL1_2 may be disposed on the first sub-light emitting layer EL1_1. The second auxiliary layer AL1_2 may have a single-layer structure or a multi-layer structure. For example, the second auxiliary layer AL1_2 may include a buffer layer and an electron transport layer (ETL).

The first charge generation layer CGL1 may be disposed on the second auxiliary layer AL1_2. The first charge generation layer CGL1 may have a single-layer structure or a multi-layer structure. The first charge generation layer CGL1 may adjust a charge balance between the first sub-light emitting layer EL1_1 and the second sub-light emitting layer EL1_2. For example, the first charge generation layer CGL1 may include an n-type charge generation layer that provides an electron to the first sub-light emitting layer EL1_1 and a p-type charge generation layer that provides a hole to the second sub-light emitting layer EL1_2.

The third auxiliary layer AL1_3 may be disposed on the first charge generation layer CGL1. The third auxiliary layer AL1_3 may have a single-layer structure or a multi-layer structure. For example, the third auxiliary layer AL1_3 may include a hole transport layer.

The second sub-light emitting layer EL1_2 may be disposed on the third auxiliary layer AL1_3. The second sub-light emitting layer EL1_2 may overlap the first sub-light emitting layer EL1_1 in a plan view. The second sub-light emitting layer EL1_2 may emit light of a specific wavelength band, and may include a material that emits the light. In an embodiment, the second sub-light emitting layer EL1_2 may emit light of a same wavelength band as the first sub-light emitting layer EL1_1. For example, the second sub-light emitting layer EL1_2 may emit light of a blue wavelength band, but the present disclosure is not limited thereto.

The fourth auxiliary layer AL1_4 may be disposed on the second sub-light emitting layer EL1_2. The fourth auxiliary layer AL1_4 may have a single-layer structure or a multi-layer structure. For example, the fourth auxiliary layer AL1_4 may include an electron transport layer and a buffer layer.

The second charge generation layer CGL2 may be disposed on the fourth auxiliary layer AL1_4. The second charge generation layer CGL2 may have a single-layer structure or a multi-layer structure. For example, the second charge generation layer CGL2 may include an n-type charge generation layer and a p-type charge generation layer.

The first buffer layer BFL1 may be disposed on the second charge generation layer CGL2. The first buffer layer BFL1 may protect the first and second sub-light emitting layers EL1_1 and EL1_2 from external moisture, oxygen, or the like.

The fifth auxiliary layer AL1_5 may be disposed on the first buffer layer BFL1. The fifth auxiliary layer AL1_5 may have a single-layer or multi-layer structure. For example, the fifth auxiliary layer AL1_5 may include an electron injection layer (EIL).

In an embodiment, the second intermediate layer ML2 may have a structure in which a plurality of light emitting layers that emit light of different wavelength bands are stacked. For example, the second intermediate layer ML2 may have a structure in which an organic light emitting layer that emits light of a red wavelength band and an organic light emitting layer that emits light of a green wavelength band are stacked, and may emit light of a red wavelength band and light of a green wavelength band, but the present disclosure is not limited thereto.

The first sub-layer ML2_1 may include a first auxiliary layer AL2_1, a second light emitting layer EL2, a second auxiliary layer AL2_2, a third auxiliary layer AL2_3, a first sub-common electrode CE1, a first sub-pixel electrode PE1, a fourth auxiliary layer AL2_4, a third light emitting layer EL3, a second buffer layer BFL2, a fifth auxiliary layer AL2_5, and a sixth auxiliary layer AL2_6.

The first auxiliary layer AL2_1 may have a single-layer structure or a multi-layer structure. For example, the first auxiliary layer AL2_1 may include a hole injection layer and a hole transport layer.

The second light emitting layer EL2 may be disposed on the first auxiliary layer AL2_1. The second light emitting layer EL2 may emit light of a specific wavelength band, and may include a material that emits the light. For example, the second light emitting layer EL2 may emit light of a red wavelength band, but the present disclosure is not limited thereto.

The second auxiliary layer AL2_2 may be disposed on the second light emitting layer EL2. The second auxiliary layer AL2_2 may have a single-layer structure or a multi-layer structure. For example, the second auxiliary layer AL2_2 may include a buffer layer and an electron transport layer.

The third auxiliary layer AL2_3 may be disposed on the second auxiliary layer AL2_2. The third auxiliary layer AL2_3 may have a single-layer structure or a multi-layer structure. For example, the third auxiliary layer AL2_3 may include an electron injection layer.

The first sub-common electrode CE1 may be disposed on the third auxiliary layer AL2_3. The first sub-common electrode CE1 may include a metal, an alloy, a conductive metal oxide, a conductive metal nitride, a transparent conductive material, or the like. These may be used alone or in combination with each other.

In an embodiment, in the first sub-area LA2_1 of the second light emitting area LA2, the pixel electrode PE, the second light emitting layer EL2, and the first sub-common electrode CE1 may form a light emitting element. For example, the light emitting element may emit light of a red wavelength band in the first sub-area LA2_1, but the present disclosure is not limited thereto.

The first sub-pixel electrode PE1 may be disposed on the first sub-common electrode CE1. The first sub-pixel electrode PE1 may be electrically connected to the transistor TR. The first sub-pixel electrode PE1 may include a metal, an alloy, a conductive metal oxide, a conductive metal nitride, a transparent conductive material, or the like. These may be used alone or in combination with each other.

The fourth auxiliary layer AL2_4 may be disposed on the first sub-pixel electrode PE1. The fourth auxiliary layer AL2_4 may have a single-layer structure or a multi-layer structure. For example, the fourth auxiliary layer AL2_4 may include a hole injection layer and a hole transport layer.

The third light emitting layer EL3 may be disposed on the fourth auxiliary layer AL2_4. The third light emitting layer EL3 may overlap the second light emitting layer EL2 in a plan view. The third light emitting layer EL3 may emit light of a specific wavelength band, and may include a material that emits the light. In an embodiment, the third light emitting layer EL3 may emit light of a wavelength band different from that of the second light emitting layer EL2. For example, the third light emitting layer EL3 may emit light of a green wavelength band, but the present disclosure is not limited thereto.

The second buffer layer BFL2 may be disposed on the third light emitting layer EL3. The second buffer layer BFL2 may protect the second and third light emitting layers EL2 and EL3 from external moisture, oxygen, or the like.

The fifth auxiliary layer AL2_5 may be disposed on the second buffer layer BFL2. The fifth auxiliary layer AL2_5 may have a single-layer structure or a multi-layer structure. For example, the fifth auxiliary layer AL2_5 may include an electron transport layer.

The sixth auxiliary layer AL2_6 may be disposed on the fifth auxiliary layer AL2_5. The sixth auxiliary layer AL2_6 may have a single-layer structure or a multi-layer structure. For example, the sixth auxiliary layer AL2_6 may include an electron injection layer.

The second sub-layer ML2_2 may have a stacked structure substantially same as or similar to the first sub-layer ML2_1, except for a stacking order of the second and third light emitting layers EL2 and EL3. In an embodiment, in the first sub-layer ML2_1, the second light emitting layer EL2 may be disposed between the first substrate SUB1 and the third light emitting layer EL3, and in the second sub-layer ML2_2, the third light emitting layer EL3 may be disposed between the first substrate SUB1 and the second light emitting layer EL2.

The second sub-layer ML2_2 may include the first auxiliary layer AL2_1, the third light emitting layer EL3, the second auxiliary layer AL2_2, the third auxiliary layer AL2_3, a second sub-common electrode CE2, a second sub-pixel electrode PE2, the fourth auxiliary layer AL2_4, the second light emitting layer EL2, the second buffer layer BFL2, the fifth auxiliary layer AL2_5, and the sixth auxiliary layer AL2_6. The second sub-common electrode CE2 may correspond to the first sub-common electrode CE1, and the second sub-pixel electrode PE2 may correspond to the first sub-pixel electrode PE1.

The third light emitting layer EL3, the second auxiliary layer AL2_2, the third auxiliary layer AL2_3, the second sub-common electrode CE2, the second sub-pixel electrode PE2, the fourth auxiliary layer AL2_4, the second light emitting layer EL2, the second buffer layer BFL2, the fifth auxiliary layer AL2_5, and the sixth auxiliary layer AL2_6 may be sequentially disposed on the first auxiliary layer AL2_1.

In an embodiment, in the second sub-area LA2_2 of the second light emitting area LA2, the pixel electrode PE, the third light emitting layer EL3, and the second sub-common electrode CE2 may form a light emitting element. For example, the light emitting element may emit light of a green wavelength band in the second sub-area LA2_2, but the present disclosure is not limited thereto.

In an embodiment, the third intermediate layer ML3 may have a structure in which an organic layer that transmits light or emits light of a specific wavelength band is stacked. For example, light transmittance of the third intermediate layer ML3 may be adjusted depending on an applied voltage.

The third intermediate layer ML3 may include a first auxiliary layer AL3_1, an organic layer OL, a third buffer layer BFL3, a second auxiliary layer AL3_2, and a third auxiliary layer AL3_3.

The first auxiliary layer AL3_1 may have a single-layer structure or a multi-layer structure. For example, the first auxiliary layer AL3_1 may include a hole injection layer and a hole transport layer.

The organic layer OL may be disposed on the first auxiliary layer AL3_1. The organic layer OL may include an electrochromic organic material. In an embodiment, the organic layer OL may include viologen. The organic layer OL may transmit incident light or emit light of a specific wavelength band. A wavelength band of light emitted by the organic layer OL may be variously changed and set depending on purpose, use, manufacturing cost, or the like of the display device 10. For example, the organic layer OL may emit light of a blue wavelength band, but the present disclosure is not limited thereto.

The third buffer layer BFL3 may be disposed on the organic layer OL. The third buffer layer BFL3 may protect the organic layer OL from external moisture, oxygen, or the like.

The second auxiliary layer AL3_2 may be disposed on the third buffer layer BFL3. The second auxiliary layer AL3_2 may have a single-layer structure or a multi-layer structure. For example, the second auxiliary layer AL3_2 may include an electron transport layer.

The third auxiliary layer AL3_3 may be disposed on the second auxiliary layer AL3_2. The third auxiliary layer AL3_3 may have a single-layer structure or a multi-layer structure. For example, the third auxiliary layer AL3_3 may include an electron injection layer.

In an embodiment, the first, second, and third buffer layers BFL1, BFL2, and BFL3 may compensate for a step difference between the first, second, and third intermediate layers ML1, ML2, and ML3. For example, the first, second, and third intermediate layers ML1, ML2, and ML3 may have different stacked structures, and the first, second, and third intermediate layers ML1, ML2, and ML3 may have substantially same or similar thickness through the first, second, and third buffer layers BFL1, BFL2, and BFL3. Each of the first, second, and third buffer layers BFL1, BFL2, and BFL3 may have a single-layer structure or a multi-layer structure. Each of the first, second, and third buffer layers BFL1, BFL2, and BFL3 may further include an additional functional layer.

Although FIGS. 5 and 6 illustrate that the first intermediate layer ML1 includes five auxiliary layers AL1_1, AL1_2, AL1_3, AL1_4, and AL1_5, two light emitting layers EL1_1 and EL1_2, two charge generation layers CGL1 and CGL2, and one buffer layer BFL1, the second intermediate layer ML2 includes six auxiliary layers AL2_1, AL2_3, AL2_4, AL2_5, and AL2_6, two light emitting layers EL2 and EL3, two electrode layers CE1, CE2, PE1, and PE2, and one buffer layer BFL2, and the third intermediate layer ML3 includes three auxiliary layers AL3_1, AL3_2, and AL3_3, one organic layer OL, and one buffer layer BFL3, the present disclosure is not limited thereto. A number, type, and stacking order of layers included in the first, second, and third intermediate layers ML1, ML2, and ML3 may be variously changed.

The common electrode CE may be disposed on the first, second, and third intermediate layers ML1, ML2, and ML3. For example, the common electrode CE may continuously extend in the display area DA. For example, the common electrode CE may be disconnected between the first and second light emitting areas LA1 and LA2 and the transmissive area TA. The common electrode CE may include a metal, an alloy, a conductive metal oxide, a conductive metal nitride, a transparent conductive material, or the like. These may be used alone or in combination with each other.

In an embodiment, in the first light emitting area LA1, the pixel electrode PE, the first and second sub-light emitting layers EL1_1 and EL1_2, and the common electrode CE may form a light emitting element. Since the light emitting element includes the first and second sub-light emitting layers EL1_1 and EL1_2, power consumption of the display device 10 may be reduced, and reduction in lifespan of the display device 10 may be prevented. For example, the light emitting element may emit light in a blue wavelength band in the first light emitting area LA1, but the present disclosure is not limited thereto.

In an embodiment, in the first sub-area LA2_1 of the second light emitting area LA2, the sub-pixel electrode PE1, the third light emitting layer EL3, and the common electrode CE may form a light emitting element. For example, the light emitting element may emit light in a green wavelength band in the first sub-area LA2_1, but the present disclosure is not limited thereto.

In an embodiment, in the second sub-area LA2_2 of the second light emitting area LA2, the sub-pixel electrode PE2, the second light emitting layer EL2, and the common electrode CE may form a light emitting element. For example, the light emitting element may emit light of a red wavelength band in the second sub-area LA2_2, but the present disclosure is not limited thereto.

In the first and second sub-areas LA2_1 and LA2_2, brightness of light emitted by the second light emitting layer EL2 and brightness of light emitted by the third light emitting layer EL3 may be different. Since the third light emitting layer EL3 is disposed on the second light emitting layer EL2 in the first sub-area LA2_1 and the second light emitting layer EL2 is disposed on the third light emitting layer EL3 in the second sub-area LA2_2, brightness of light emitted by the second light emitting layer EL2 may be reduced in the first sub-area LA2_1, and brightness of light emitted by the third light emitting layer EL3 may be reduced in the second sub-area LA2_2. In an embodiment, in the pixel PX, the first sub-area LA2_1 and the second sub-area LA2_2 may be adjacent to each other and the transmissive area TA may be disposed between the first sub-area LA2_1 and the second sub-area LA2_2, so that reduced brightness may be compensated.

In an embodiment, in the transmissive area TA, the pixel electrode PE, the organic layer OL, and the common electrode CE may form an electrochromic element. The light transmittance of the electrochromic element may be adjusted depending on an applied voltage. For example, when a voltage is not applied, the electrochromic element may be transparent to transmit incident light, and the transmissive area TA may be transparent. Accordingly, a user may visually recognize an object, an image, or the like located at an opposite side. For example, when a voltage is applied, the electrochromic element may emit light of a specific wavelength band, and the transmissive area TA may be opaque. Accordingly, the user may visually recognize a specific image. That is, transparency of the transmissive area TA may be adjusted.

The capping layer CPL may be disposed on the common electrode CE. The capping layer CPL may protect the common electrode CE. The capping layer CPL may include an inorganic material such as silicon oxide, silicon nitride, silicon oxynitride, or the like, or an organic material such as a phenol resin, an acrylic resin, a polyimide resin, or the like. These may be used alone or in combination with each other.

The encapsulation layer TFE may be disposed on the capping layer CPL. The encapsulation layer TFE may protect the light emitting elements from external moisture, oxygen, or the like. The encapsulation layer TFE may include at least one inorganic layer and at least one organic layer.

The second substrate SUB2 may include a transparent material or an opaque material. For example, the second substrate SUB2 may include glass, plastic, flexible film, metal, or the like.

The display device 10 according to an embodiment of the present disclosure may include the third intermediate layer ML3 disposed in the transmissive area TA and including an electrochromic organic material. The transmissive area TA may transmit incident light or emit light of a specific wavelength band, depending on case, and accordingly, transparency of the display device 10 may be adjusted. In addition, the first and second sub-areas LA2_1 and LA2_2 having different stacking orders of the second and third light emitting layers EL2 and EL3 that emit light of different wavelength bands may be adjacent to each other. Accordingly, brightness of light emitted by a layer disposed lower among the second and third light emitting layers EL2 and EL3 in the first and second sub-areas LA2_1 and LA2_2 may be compensated.

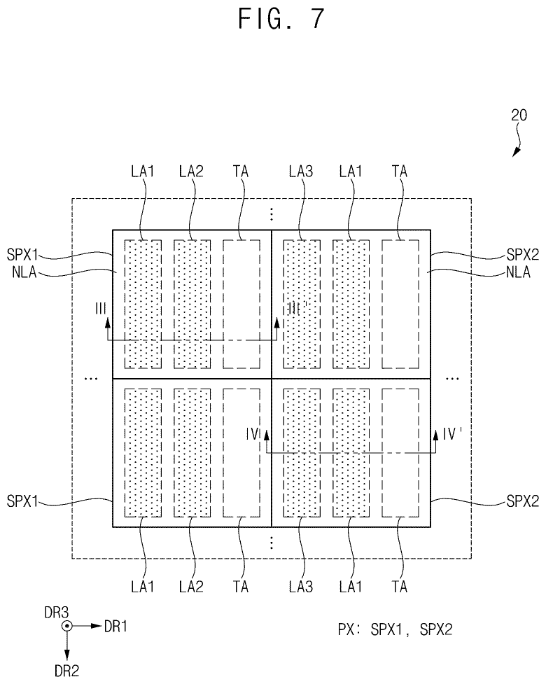

FIG. 7 is a plan view illustrating a display device according to an embodiment of the present disclosure. FIG. 7 may correspond to the plan view of FIG. 2. FIG. 7 may be an enlarged plan view of a portion of a display area of a display device 20.

Hereinafter, descriptions overlapping the display device 10 described with reference to FIGS. 1, 2, 3, 4, 5, and 6 will be omitted or simplified.

Referring to FIG. 7, the display device 20 may include pixels PX disposed in the display area. The pixels PX may include a first light emitting area LA1, a second light emitting area LA2, a third light emitting area LA3, a transmissive area TA, and a non-light emitting area NLA.

Each of the first light emitting area LA1, the second light emitting area LA2, and the third light emitting area LA3 may be an area that emits light. The first light emitting area LA1, the second light emitting area LA2, and the third light emitting area LA3 may emit light of different wavelength bands.

The transmissive area TA may be an area that transmits incident light. In addition, the transmissive area TA may be an area that emits light of a specific wavelength band. In an embodiment, the transmissive area TA may be an area in which light transmittance is adjusted. As the display device 20 includes the transmissive area TA, transparency of the display device 20 may be adjusted.

The non-light emitting area NLA may be an area that does not emit light. The non-light emitting area NLA may partition the first light emitting area LA1, the second light emitting area LA2, the third light emitting area LA3, and the transmissive area TA.

The pixels PX may include a first sub-pixel SPX1 and a second sub-pixel SPX2. The first sub-pixel SPX1 and the second sub-pixel SPX2 may be alternately arranged along a first direction DR1, and each of the first sub-pixel SPX1 and the second sub-pixel SPX2 may be repeatedly arranged along a second direction DR2 intersecting the first direction DR1.

The first sub-pixel SPX1 may include the first light emitting area LA1, the second light emitting area LA2, and the transmissive area TA, and the second sub-pixel SPX2 may include the first light emitting area LA1, the third light emitting area LA3, and the transmissive area TA.

In an embodiment, in the first sub-pixel SPX1, the second light emitting area LA2 may be spaced apart from the first light emitting area LA1 in the first direction DR1, and the transmissive area TA may be spaced apart from the second light emitting area LA2 in the first direction DR1. In the second sub-pixel SPX2, the first light emitting area LA1 may be spaced apart from the third light emitting area LA3 in the first direction DR1, and the transmissive area TA may be spaced apart from the first light emitting area LA1 in the first direction DR1. That is, in the first and second sub-pixels SPX1 and SPX2, arrangement of the transmissive area TA may be same, but arrangement of the first, second, and third light emitting areas LA1, LA2, and LA3 may be different. However, the present disclosure is not limited thereto, and in the first and second sub-pixels SPX1 and SPX2 (or in the pixels PX), the arrangement of the first, second, and third light emitting areas LA1, LA2, and LA3 and the transmissive area TA may be variously changed.

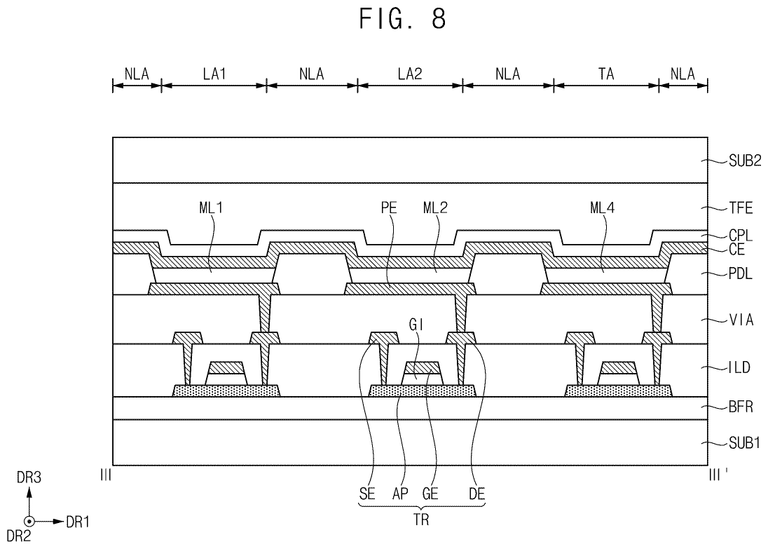

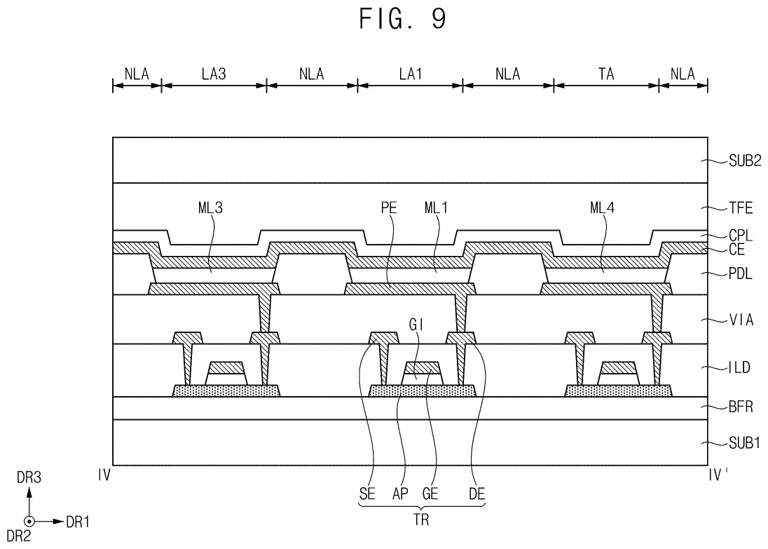

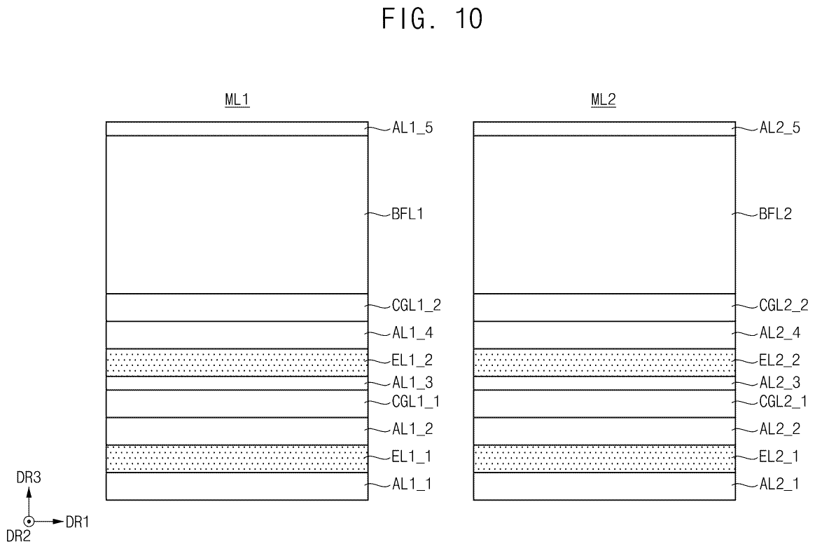

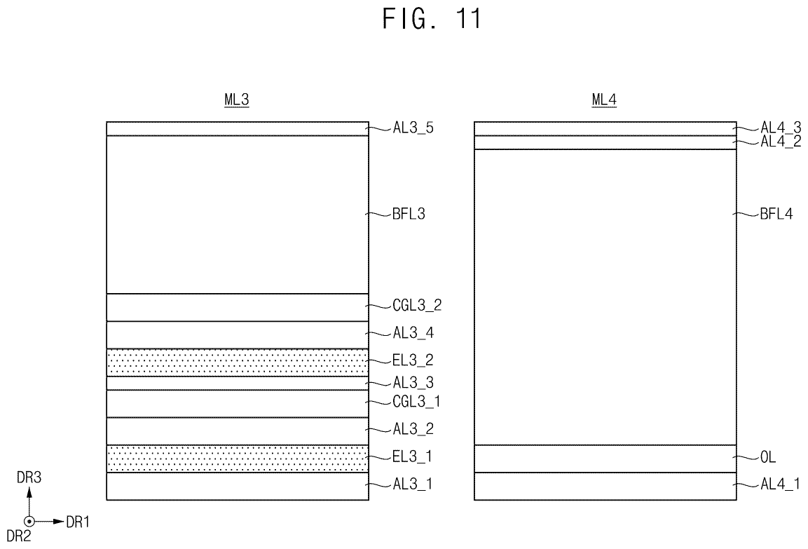

FIG. 8 is a cross-sectional view taken along line III-III′ of FIG. 7. FIG. 9 is a cross-sectional view taken along line IV-IV′ of FIG. 7. FIGS. 10 and 11 are cross-sectional views illustrating an intermediate layer included in the display device of FIG. 7.

For example, FIG. 8 may be a cross-sectional view illustrating the first sub-pixel SPX1, and FIG. 9 may be a cross-sectional view illustrating the second sub-pixel SPX2. FIG. 10 may be a cross-sectional view illustrating a first intermediate layer ML1 disposed in the first light emitting area LA1 and a second intermediate layer ML2 disposed in the second light emitting area LA2. FIG. 11 may be a cross-sectional view illustrating a third intermediate layer ML3 disposed in the third light emitting area LA3 and a fourth intermediate layer ML4 disposed in the transmissive area TA.

Referring to FIGS. 7, 8, 9, 10, and 11, the display device 20 may include a first substrate SUB1, a buffer layer BFR, a transistor TR, a gate insulating layer GI, an interlayer insulating layer ILD, a via insulating layer VIA, a pixel electrode PE, a pixel defining layer PDL, the first intermediate layer ML1, the second intermediate layer ML2, the third intermediate layer ML3, the fourth intermediate layer ML4, a common electrode CE, a capping layer CPL, an encapsulation layer TFE, and a second substrate SUB2. The transistor TR may include an active pattern AP, a gate electrode GE, a source electrode SE, and a drain electrode DE.

The buffer layer BFR, the active pattern AP, the gate insulating layer GI, the gate electrode GE, the interlayer insulating layer ILD, the source electrode SE, the drain electrode DE, the via insulating layer VIA, the pixel electrode PE, and the pixel defining layer PDL may be sequentially disposed on the first substrate SUB1.

The first, second, third, and fourth intermediate layers ML1, ML2, ML3, and ML4 may be disposed on the pixel electrode PE. The first intermediate layer ML1 may be disposed in the first light emitting area LA1, the second intermediate layer ML2 may be disposed in the second light emitting area LA2, the third intermediate layer ML3 may be disposed in the third light emitting area LA3, and the fourth intermediate layer ML4 may be disposed in the transmissive area TA.

Each of the first, second, third, and fourth intermediate layers ML1, ML2, ML3, and ML4 may have a multi-layer structure. For example, the first, second, and third intermediate layers ML1, ML2, and ML3 may have similar stacked structures, and the fourth intermediate layer ML4 may have a different stacked structure from the first, second, and third intermediate layers ML1, ML2, and ML3.

In an embodiment, the first, second, and third intermediate layers ML1, ML2, and ML3 may have a structure in which a plurality of light emitting layers that emit light of a same wavelength band are stacked. For example, the first intermediate layer ML1 may have a structure in which a plurality of organic light emitting layers that emit light of a blue wavelength band are stacked, and may emit light of a blue wavelength band. The second intermediate layer ML2 may have a structure in which a plurality of organic light emitting layers that emit light of a green wavelength band are stacked, and may emit light of a green wavelength band. The third intermediate layer ML3 may have a structure in which a plurality of organic light emitting layers that emit light of a red wavelength band are stacked, and may emit light of a red wavelength band. However, the present disclosure is not limited thereto.

The first intermediate layer ML1 may include a first auxiliary layer AL1_1, a first light emitting layer EL1_1, a second auxiliary layer AL1_2, a first charge generation layer CGL1_1, a third auxiliary layer AL1_3, a second light emitting layer EL1_2, a fourth auxiliary layer AL1_4, a second charge generation layer CGL1_2, a buffer layer BFL1, and a fifth auxiliary layer AL1_5.

The first auxiliary layer AL1_1 may be disposed on the pixel electrode PE. For example, the first auxiliary layer AL1_1 may include a hole injection layer and a hole transport layer.

The first light emitting layer EL1_1 may be disposed on the first auxiliary layer AL1_1. The first light emitting layer EL1_1 may emit light of a specific wavelength band, and may include a material that emits the light. For example, the first light emitting layer EL1_1 may emit light of a blue wavelength band, but the present disclosure is not limited thereto.

The second auxiliary layer AL1_2 may be disposed on the first light emitting layer EL1_1. For example, the second auxiliary layer AL1_2 may include a buffer layer and an electron transport layer.

The first charge generation layer CGL1_1 may be disposed on the second auxiliary layer AL1_2. For example, the first charge generation layer CGL1_1 may include an n-type charge generation layer that provides an electron to the first light emitting layer EL1_1 and a p-type charge generation layer that provides a hole to the second light emitting layer EL1_2.

The third auxiliary layer AL1_3 may be disposed on the first charge generation layer CGL1_1. For example, the third auxiliary layer AL1_3 may include a hole transport layer.

The second light emitting layer EL1_2 may be disposed on the third auxiliary layer AL1_3. The second light emitting layer EL1_2 may overlap the first light emitting layer EL1_1 in a plan view. The second light emitting layer EL1_2 may emit light of a specific wavelength band, and may include a material that emits the light. In an embodiment, the second light emitting layer EL1_2 may emit light of a same wavelength band as the first light emitting layer EL1_1. For example, the second light emitting layer EL1_2 may emit light of a blue wavelength band, but the present disclosure is not limited thereto.

The fourth auxiliary layer AL1_4 may be disposed on the second light emitting layer EL1_2. For example, the fourth auxiliary layer AL1_4 may include an electron transport layer and a buffer layer.

The second charge generation layer CGL1_2 may be disposed on the fourth auxiliary layer AL1_4. For example, the second charge generation layer CGL1_2 may include an n-type charge generation layer and a p-type charge generation layer.

The buffer layer BFL1 may be disposed on the second charge generation layer CGL1_2. The buffer layer BFL1 may protect the first and second light emitting layers EL1_1 and EL1_2 from external moisture, oxygen, or the like.

The fifth auxiliary layer AL1_5 may be disposed on the buffer layer BFL1. For example, the fifth auxiliary layer AL1_5 may include an electron injection layer.

The second intermediate layer ML2 may include a first auxiliary layer AL2_1, a first light emitting layer EL2_1, a second auxiliary layer AL2_2, a first charge generation layer CGL2_1, a third auxiliary layer AL2_3, a second light emitting layer EL2_2, a fourth auxiliary layer AL2_4, a second charge generation layer CGL2_2, a buffer layer BFL2, and a fifth auxiliary layer AL2_5.

The first light emitting layer EL2_1, the second auxiliary layer AL2_2, the first charge generation layer CGL2_1, the third auxiliary layer AL2_3, the second light emitting layer EL2_2, the fourth auxiliary layer AL2_4, the second charge generation layer CGL2_2, the buffer layer BFL2, and the fifth auxiliary layer AL2_5 may be sequentially disposed on the first auxiliary layer AL2_1.

The first light emitting layer EL2_1 and the second light emitting layer EL2_2 may overlap each other in a plan view. Each of the first and second light emitting layers EL2_1 and EL2_2 may emit light of a specific wavelength band, and may include a material that emits the light. In an embodiment, the first and second light emitting layers EL2_1 and EL2_2 may emit light of a same wavelength band. For example, each of the first and second light emitting layers EL2_1 and EL2_2 may emit light of a green wavelength band, but the present disclosure is not limited thereto.

The third intermediate layer ML3 may include a first auxiliary layer AL3_1, a first light emitting layer EL3_1, a second auxiliary layer AL3_2, a first charge generation layer CGL3_1, a third auxiliary layer AL3_3, a second light emitting layer EL3_2, a fourth auxiliary layer AL3_4, a second charge generation layer CGL3_2, a buffer layer BFL3, and a fifth auxiliary layer AL3_5.

The first light emitting layer EL3_1, the second auxiliary layer AL3_2, the first charge generation layer CGL3_1, the third auxiliary layer AL3_3, the second light emitting layer EL3_2, the fourth auxiliary layer AL3_4, the second charge generation layer CGL3_2, the buffer layer BFL3, and the fifth auxiliary layer AL3_5 may be sequentially disposed on the first auxiliary layer AL3_1.

The first light emitting layer EL3_1 and the second light emitting layer EL3_2 may overlap each other in a plan view. Each of the first and second light emitting layers EL3_1 and EL3_2 may emit light of a specific wavelength band, and may include a material that emits the light. In an embodiment, the first and second light emitting layers EL3_1 and EL3_2 may emit light of a same wavelength band. For example, each of the first and second light emitting layers EL3_1 and EL3_2 may emit light of a red wavelength band, but the present disclosure is not limited thereto.

In an embodiment, the fourth intermediate layer ML4 may have a structure in which an organic layer that transmits incident light or emits light of a specific wavelength band is stacked. For example, light transmittance of the fourth intermediate layer ML4 may be adjusted depending on an applied voltage.

The fourth intermediate layer ML4 may include a first auxiliary layer AL4_1, an organic layer OL, a buffer layer BFL4, a second auxiliary layer AL4_2, and a third auxiliary layer AL4_3.

The organic layer OL, the buffer layer BFL4, the second auxiliary layer AL4_2, and the third auxiliary layer AL4_3 may be sequentially disposed on the first auxiliary layer AL4_1.

The organic layer OL may include an electrochromic organic material. In an embodiment, the organic layer OL may include viologen. The organic layer OL may transmit incident light or emit light of a specific wavelength band. A wavelength band of light emitted by the organic layer OL may be variously changed and set depending on purpose, use, manufacturing cost, or the like of the display device 20. For example, the organic layer OL may emit light in a blue wavelength band, but the present disclosure is not limited thereto.

Although FIGS. 10 and 11 illustrates that each of the first, second, and third intermediate layers ML1, ML2, and ML3 includes five auxiliary layers, two light emitting layers, two charge generation layers, and one buffer layer, and the fourth intermediate layer ML4 includes three auxiliary layers, one organic layer, and one buffer layer, the present disclosure is not limited thereto. A number, type, and stacking order of layers included in the first, second, third, and fourth intermediate layers ML1, ML2, ML3, and ML4 may be variously changed.

The common electrode CE, the capping layer CPL, the encapsulation layer TFE, and the second substrate SUB2 may be sequentially disposed on the first, second, third, and fourth intermediate layers ML1, ML2, ML3, and ML4.

In an embodiment, in the first light emitting area LA1, the pixel electrode PE, the first and second light emitting layers EL1_1 and EL1_2, and the common electrode CE may form a light emitting element. In the second light emitting area LA2, the pixel electrode PE, the first and second light emitting layers EL2_1 and EL2_2, and the common electrode CE may form a light emitting element. In the third light emitting area LA3, the pixel electrode PE, the first and second light emitting layers EL3_1 and EL3_2, and the common electrode CE may form a light emitting element. Since each of the light emitting elements includes the first and second light emitting layers, power consumption of the display device 20 may be reduced, and reduction in lifespan of the display device 20 may be prevented. For example, the light emitting element in the first light emitting area LA1 may emit light of a blue wavelength band, the light emitting element in the second light emitting area LA2 may emit light of a green wavelength band, and the light emitting element in the third light emitting area LA3 may emit light of a red wavelength band, but the present disclosure is not limited thereto.

In an embodiment, in the transmissive area TA, the pixel electrode PE, the organic layer OL, and the common electrode CE may form an electrochromic element. The light transmittance of the electrochromic element may be adjusted depending on an applied voltage. For example, when a voltage is not applied, the electrochromic element may be transparent to transmit light, and the transmissive area TA may be transparent. Accordingly, a user may visually recognize an object, an image, or the like located at an opposite side. For example, when a voltage is applied, the electrochromic element may emit light of a specific wavelength band, and the transmissive area TA may be opaque. Accordingly, the user may visually recognize a specific image. That is, transparency of the transmissive area TA may be adjusted.

The display device 20 according to an embodiment of the present disclosure may include the fourth intermediate layer ML4 disposed in the transmissive area TA and including an electrochromic organic material. The transmissive area TA may transmit incident light or emit light of a specific wavelength band, depending on case, and accordingly, transparency of the display device 20 may be adjusted.

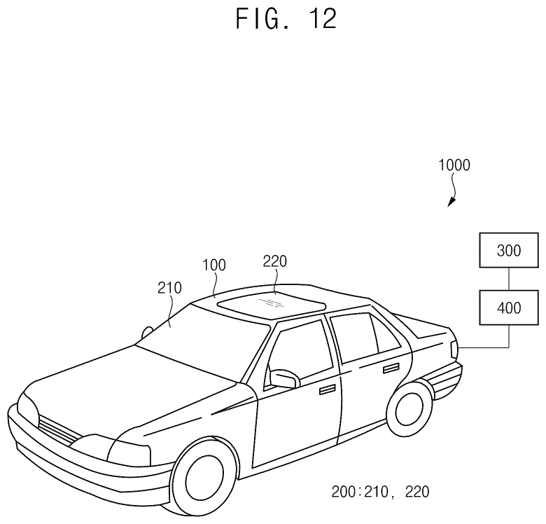

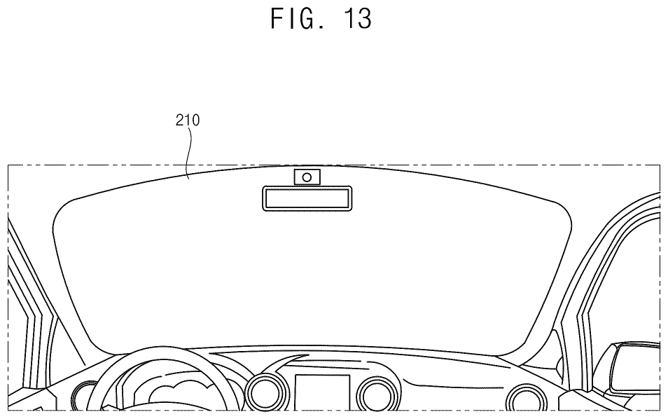

FIG. 12 is a view schematically illustrating a vehicle 1000 according to an embodiment of the present disclosure. FIG. 13 is a view schematically illustrating a portion of an interior of the vehicle 1000 of FIG. 12.

Referring to FIGS. 12 and 13, the vehicle 1000 may include a vehicle body 100, a display device 200, a detector 300, and a controller 400.

For example, the vehicle 1000 may be an autonomous driving vehicle. Autonomous driving may mean that driving operation device is automatically operated even when a user input is not input to the driving operation device. The vehicle 1000 may be switched to an autonomous driving mode or a manual mode based on the user input.

The vehicle body 100 may form an exterior of the vehicle 1000, and may define an interior space in which a driver and a passenger ride. The vehicle body 100 may include a front window glass that protects the driver and the passenger from outside and provides a view to the driver, and a sunroof that allows external light and air to enter the interior space of the vehicle 1000.

The display device 200 may be disposed on the vehicle body 100. For example, the display device 200 may correspond to the display device 10 described with reference to FIG. 1, 2, 3, 4, 5, and 6 or the display device 20 described with reference to FIGS. 7, 8, 9, 10, and 11. That is, the display device 200 may have a structure substantially same as or similar to that of the display device 10 described with reference to FIG. 1, 2, 3, 4, 5, and 6 or the display device 20 described with reference to FIGS. 7, 8, 9, 10, and 11.

The detector 300 may be a device that detects an object located outside the vehicle 1000. The object may include a lane including a driving lane or the like, another vehicle including a two-wheeled vehicle or the like, a pedestrian, a traffic signal including a traffic light, a sign, or the like, light including sunlight, light generated by another vehicle, or the like, and a structure including a speed bump, a building, or the like.

For example, the detector 300 may include a camera module. The detector 300 may be located at a suitable location of the vehicle 1000 to obtain an external image of the vehicle 1000. For example, the detector 300 may be located around a front bumper, the front window glass, or the like of the vehicle 1000 to obtain a front image of the vehicle 1000 (i.e., an image recognizable through the front window glass).

The detector 300 may provide the obtained image to the controller 400. The controller 400 may detect and track the object based on the image. For example, the controller 400 may perform operations such as calculating a distance to the object, calculating a relative speed with the object, calculating an intensity of the object, or the like. The controller 400 may control the display device 200 according to the calculated result.

The display device 200 may include a first display area 210 and a second display area 220. For example, the first display area 210 may be disposed on the front window glass, and the second display area 220 may be disposed on the sunroof.

When describing based on the first display area 210, the detector 300 may provide a front image of the vehicle 1000 to the controller 400, and the controller 400 may detect the front image and control transparency of the first display area 210.

For example, when intensity of sunlight outside the vehicle 1000 is strong, the controller 400 may display the first display area 210 opaquely to prevent the driver's glare.

For example, when it is difficult to check a lane due to fog outside the vehicle 1000, the controller 400 may display a virtual lane on the lane in the first display area 210 to make the driver recognize the lane.

For example, the controller 400 may display information related to an external traffic situation of the vehicle 1000 in the first display area 210. For example, when the vehicle 1000 is switched to the autonomous driving mode, the controller 400 may display a specific screen on the first display area 210 instead of an external traffic situation. For example, the controller 400 may not display additional information or a specific screen through the first display area 210, and the driver and the passenger may recognize an external traffic situation through the first display area 210 (i.e., through the front window glass).

Although FIGS. 12 and 13 illustrate that the display device 200 is disposed on the front window glass and the sunroof, the present disclosure is not limited thereto. For example, the display device 200 may be variously disposed in the vehicle 1000, such as being disposed on a dashboard.

In addition, the display devices 10 and 20 according to embodiments of the present disclosure are not limited to being applied only to the display device 200 disposed in the vehicle 1000 of FIGS. 12 and 13, and may be applied to various display devices.

The display devices 10 and 20 according to embodiments of the present disclosure may be applied to various electronic devices. An electronic device according to an embodiment of the present disclosure may include the display device 10 or the display device 20 described above, and may further include a module or device having additional functions in addition to the display device 10 or the display device 20.

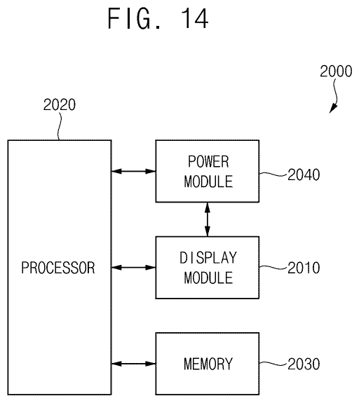

FIG. 14 is a block diagram illustrating an electronic device 2000 according to an embodiment of the present disclosure.

Referring to FIG. 14, the electronic device 2000 may include a display module 2010, a processor 2020, a memory 2030, and a power module 2040.

The processor 2020 may include at least one of a central processing unit (CPU), an application processor (AP), a graphic processing unit (GPU), a communication processor (CP), an image signal processor (ISP), and a controller.

The memory 2030 may store data information necessary for an operation of the processor 2020 or the display module 2010. When the processor 2020 executes an application stored in the memory 2030, an image data signal and/or an input control signal may be transmitted to the display module 2010, and the display module 2010 may process the received signal and output image information through a display screen.

The power module 2040 may include a power supply module such as a power adapter, a battery device, or the like and a power conversion module that converts power supplied by the power supply module to generate power necessary for an operation of the electronic device 2000. At least one of the components of the electronic device 2000 described above may be included in the display device according to embodiments described above. In addition, some of individual modules functionally included in one module may be included in the display device, and others may be provided separately from the display device. For example, the display device may include the display module 2010, and the processor 2020, the memory 2030, and the power module 2040 may be provided in form of other devices in the electronic device 2000 other than the display device.

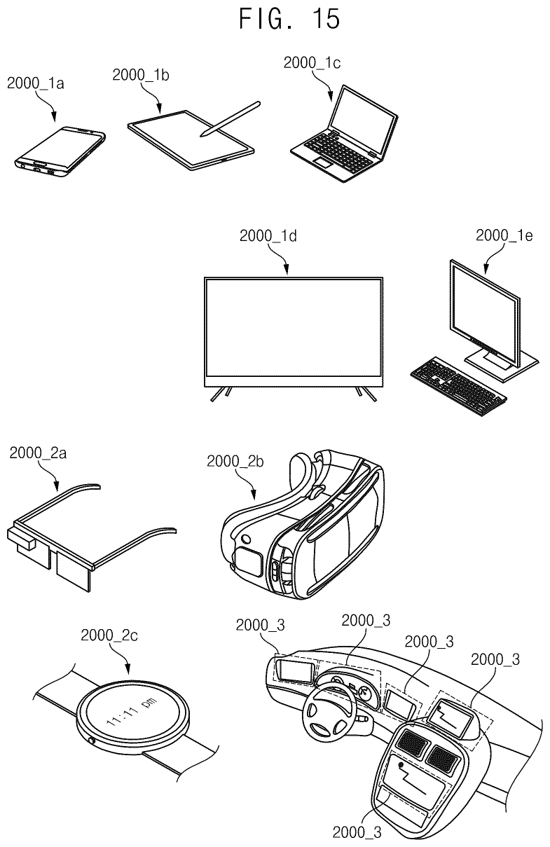

FIG. 15 is a schematic view illustrating electronic devices according to embodiments of the present disclosure.

Referring to FIG. 15, various electronic devices to which the display device according to embodiments of the present disclosure are applied may include not only an image display electronic device, but also a wearable electronic device including a display module, a vehicle electronic device 2000_3 including a display module, or the like. The image display electronic device may be a smartphone 2000_1a, a tablet PC 2000_1b, a laptop 2000_1c, a TV 2000_1d, a desk monitor 2000_1e, or the like. The wearable electronic device may be smart glasses 2000_2a, a head mounted display 2000_2b, a smart watch 2000_2c, or the like. The vehicle electronic device 2000_3 may be a center information display (CID) disposed on a dashboard and center fascia of a vehicle, a room mirror display, or the like.

The present disclosure can be applied to various display devices and electronic devices. For example, the present disclosure is applicable to various display devices such as display devices for vehicles, ships and aircraft, portable communication devices, display devices for exhibition or information transmission, medical display devices, and the like.

The foregoing is illustrative of embodiments and is not to be construed as limiting thereof. Although a few embodiments have been described, those skilled in the art will readily appreciate that many modifications are possible in the embodiments without materially departing from the novel teachings and advantages of the present inventive concept. Accordingly, all such modifications are intended to be included within the scope of the present inventive concept as defined in the claims. Therefore, it is to be understood that the foregoing is illustrative of various embodiments and is not to be construed as limited to the specific embodiments disclosed, and that modifications to the disclosed embodiments, as well as other embodiments, are intended to be included within the scope of the appended claims.

What is claimed is:

1. A display device comprising:
a substrate defining a first light emitting area, a second light emitting area, and a transmissive area;
a pixel electrode disposed in the first light emitting area, the second light emitting area, and the transmissive area on the substrate;
a first intermediate layer disposed in the first light emitting area on the pixel electrode and including a first light emitting layer that emits a first light;
a second intermediate layer disposed in the second light emitting area on the pixel electrode and including a second light emitting layer that emits a second light and a third light emitting layer that emits a third light;
a third intermediate layer disposed in the transmissive area on the pixel electrode and including an organic layer including an electrochromic material; and
a common electrode disposed on the first intermediate layer, the second intermediate layer, and the third intermediate layer.

2. The display device of claim 1, wherein,
the second light emitting area includes a first sub-area and a second sub-area spaced apart from the first sub-area,
the first sub-area and the second sub-area are adjacent to each other, and
the transmissive area is disposed between the first sub-area and the second sub-area.

3. The display device of claim 2, wherein the second intermediate layer includes:
a first sub-layer disposed in the first sub-area on the pixel electrode, in which the second light emitting layer is disposed between the substrate and the third light emitting layer; and
a second sub-layer disposed in the second sub-area on the pixel electrode, in which the third light emitting layer is disposed between the substrate and the second light emitting layer.

4. The display device of claim 2, wherein,
the first light emitting area, the first sub-area, and the transmissive area define a first sub-pixel,
the first light emitting area, the second sub-area, and the transmissive area define a second sub-pixel, and
the first sub-pixel and the second sub-pixel are alternately arranged along a first direction and a second direction intersecting the first direction.

5. The display device of claim 4, wherein in the first sub-pixel,
the first sub-area is spaced apart from the first light emitting area in the first direction, and
the transmissive area is spaced apart from the first sub-area in the first direction.

6. The display device of claim 4, wherein in the second sub-pixel,
the first light emitting area is spaced apart from the second sub-area in the first direction, and
the transmissive area is spaced apart from the first light emitting area in the first direction.

7. The display device of claim 1, wherein the organic layer includes viologen.

8. The display device of claim 1, wherein the first light emitting layer includes:
a first sub-light emitting layer that emits the first light; and
a second sub-light emitting layer that is disposed on the first sub-light emitting layer and emits the first light.

9. The display device of claim 8, wherein,
the first intermediate layer further includes a charge generation layer disposed between the first sub-light emitting layer and the second sub-light emitting layer, and
the second intermediate layer further includes a sub-common electrode and a sub-pixel electrode disposed between the second light emitting layer and the third light emitting layer.

10. The display device of claim 1, wherein,
the first light is light of a blue wavelength band,
the second light is light of a red wavelength band, and
the third light is light of a green wavelength band.

11. A vehicle comprising:
a vehicle body defining an interior space; and
a display device disposed on the vehicle body,
wherein the display device including:
a substrate defining a first light emitting area, a second light emitting area, and a transmissive area;
a pixel electrode disposed in the first light emitting area, the second light emitting area, and the transmissive area on the substrate;
a first intermediate layer disposed in the first light emitting area on the pixel electrode and including a first light emitting layer that emits a first light;
a second intermediate layer disposed in the second light emitting area on the pixel electrode and including a second light emitting layer that emits a second light and a third light emitting layer that emits a third light;
a third intermediate layer disposed in the transmissive area on the pixel electrode and including an organic layer including an electrochromic material; and
a common electrode disposed on the first intermediate layer, the second intermediate layer, and the third intermediate layer.

12. The vehicle of claim 11, wherein,
the second light emitting area includes a first sub-area and a second sub-area spaced apart from the first sub-area,
the first sub-area and the second sub-area are adjacent to each other, and
the transmissive area is disposed between the first sub-area and the second sub-area.

13. The vehicle of claim 12, wherein the second intermediate layer includes:
a first sub-layer disposed in the first sub-area on the pixel electrode, in which the second light emitting layer is disposed between the substrate and the third light emitting layer; and
a second sub-layer disposed in the second sub-area on the pixel electrode, in which the third light emitting layer is disposed between the substrate and the second light emitting layer.

14. The vehicle of claim 12, wherein,
the first light emitting area, the first sub-area, and the transmissive area define a first sub-pixel,
the first light emitting area, the second sub-area, and the transmissive area define a second sub-pixel, and
the first sub-pixel and the second sub-pixel are alternately arranged along a first direction and a second direction intersecting the first direction.

15. The vehicle of claim 14, wherein,
in the first sub-pixel, the first sub-area is spaced apart from the first light emitting area in the first direction, and the transmissive area is spaced apart from the first sub-area in the first direction, and
in the second sub-pixel, the first light emitting area is spaced apart from the second sub-area in the first direction, and the transmissive area is spaced apart from the first light emitting area in the first direction.

16. The vehicle of claim 11, wherein the organic layer includes viologen.

17. The vehicle of claim 11, wherein the first light emitting layer includes:
a first sub-light emitting layer that emits the first light; and
a second sub-light emitting layer that is disposed on the first sub-light emitting layer and emits the first light.

18. The vehicle of claim 17, wherein,
the first intermediate layer further includes a charge generation layer disposed between the first sub-light emitting layer and the second sub-light emitting layer, and
the second intermediate layer further includes a sub-common electrode and a sub-pixel electrode disposed between the second light emitting layer and the third light emitting layer.

19. The vehicle of claim 11, wherein,
the vehicle body includes a front window glass, and
the display device is disposed on the front window glass.

20. An electronic device comprising:
a display device; and
a power module that supplies power to the display device,
wherein the display device includes:
a substrate defining a first light emitting area, a second light emitting area, and a transmissive area;
a pixel electrode disposed in the first light emitting area, the second light emitting area, and the transmissive area on the substrate;
a first intermediate layer disposed in the first light emitting area on the pixel electrode and including a first light emitting layer that emits a first light;
a second intermediate layer disposed in the second light emitting area on the pixel electrode and including a second light emitting layer that emits a second light and a third light emitting layer that emits a third light;
a third intermediate layer disposed in the transmissive area on the pixel electrode and including an organic layer including an electrochromic material; and
a common electrode disposed on the first intermediate layer, the second intermediate layer, and the third intermediate layer.
